(19) United States
(12) Patent Application Publication
(10) Pub. No.: US 2003/0141589 A1
(43) Pub. Date: Jul. 31, 2003

(54) Encapsulated high-frequency electrical circuit

(75) Inventors: Simon Leung, Richfield, MN (US); Guanghua Huang, Prior Lake, MN (US)

Correspondence Address: John C. Reich, MERCHANT & GOULD P.C., P.O. Box 2903, Minneapolis, MN, 55402-0903, US

(73) Assignee: HEI, Inc., Victoria, MN

(21) Appl. No.: 10/349,575

(22) Filed: Jan. 22, 2003

Related U.S. Application Data
(63) Continuation of application No. 09/678,355, filed on Oct. 3, 2000, now abandoned.

(51) Int. Cl. H01L 23/34

(52) U.S. Cl. 257/728

(57) ABSTRACT

An apparatus for processing a high-frequency electrical signal. The apparatus comprises a circuit carrier and an electrical circuit mounted on the circuit carrier. The electrical circuit processes a signal within a predetermined frequency range, the predetermined fundamental frequency range having a low end in the range being about 1 GHz or higher. An encapsulent material encapsulates at least a portion of the electrical circuit. The circuit carrier, electrical circuit, and encapsulent material form a package having resonant frequencies. The resonant frequencies are outside the predetermined frequency range.

### TECHNICAL FIELD

The present invention relates to high-frequency electrical circuits, and more particularly, to high-frequency electrical circuits that are encapsulated with a material that is formed around the electrical circuit.

### BACKGROUND

Electrical circuits are used in a variety of different devices and applications such as computers, radios, transmitters, and receivers. Additionally, they are exposed to a variety of different environments, some of which are hostile and can result in damage to the electronics. Examples include portable computers that are used in outdoor areas, computers and electronics mounted in automobiles, construction equipment, and farm equipment, computers and electronics used in manufacturing equipment, electronics mounted on radio towers, electronics used in telephones and portable radios, as well as electronics used in military applications.

Additionally, many of these circuits are integrated circuits or are formed using microelectronics. They are very delicate and very susceptible to damage. The result is often quality control problems during the manufacturing process, which is expensive and frustrating for customers if the damage is not identified before a product is shipped.

To prevent such damage, many electrical circuits have some type of protective cover to prevent damage from mishandling and damage from environmental factors such as moisture. One technique that is used to protect electrical circuits, especially with integrated circuits and other electrical devices and elements, is to encapsulate the electronics with a material such as epoxy. However, encapsulation tends to work only with electrical circuits that operate at low frequency. The material used to encapsulate circuitry tends to have a high dielectric constant and a high loss. As a result, the encapsulate material tends to disrupt the electric and magnetic fields that are generated by a high-frequency signal. This disruption can cause signal loss and a reduction in the signal to noise ratio.

To prevent adversely affecting high-frequency signals, a cover or cap is traditionally used to protect the circuitry. However, the protection offered by covers is inferior to the protection offered by encapsulation. The covers add more bulk and can be difficult to seal against the external environment. As a result, circuitry protected by covers still tends to be susceptible to damage from the external environment.

### SUMMARY

In general terms, the present invention is directed to a high-frequency circuit that is encapsulated with an encapsulent material. There are several aspects to this invention. One aspect is an apparatus for processing a high-frequency electrical signal. The apparatus comprises an electrical circuit arranged to process a signal having a fundamental frequency of about 1 GHz or higher. An encapsulent material encapsulates at least a portion of the electrical circuit.

An alternative aspect of the invention is an apparatus that comprises a circuit carrier. An electrical circuit is mounted on the circuit carrier. The electrical circuit processes a signal within a predetermined frequency range. The predetermined frequency range has a low end of about 20 GHz or higher. An encapsulent material encapsulates at least a portion of the electrical circuit. The circuit carrier, electrical circuit, and encapsulent material form a package that has resonant frequencies outside the predetermined frequency range.

Yet another alternative aspect of the present invention is a method of manufacturing an apparatus for processing a high-frequency electrical signal. The method comprises: providing a circuit carrier, a plurality of circuits being mounted on the circuit carrier; encapsulating at least a portion of each of the circuits; and separating the circuit carrier into two or more individual boards so that each board has at least one circuit and the encapsulent is around at least a portion of the at least one circuit on each board.

### DESCRIPTION OF THE DRAWINGS

FIG. 1 is an isometric view of one possible embodiment of an encapsulated high-frequency circuit that embodies the present invention.

FIG. 2 is a cross-sectional view, taken along line 2-2, of the encapsulated high-frequency circuit illustrated in FIG. 1

FIG. 3 is a cross-sectional view of one possible high-frequency circuit illustrated in FIG. 2.

FIG. 4 is a cross-sectional view of another possible high-frequency circuit illustrated in FIG. 2.

FIG. 5 is an isometric view of a mold for making the encapsulated high-frequency circuit illustrated in FIG. 1.

FIG. 6 is a partial isometric view of an alternative embodiment of a mold for making an encapsulated high-frequency circuit.

FIG. 7 is a partial isometric view of an alternative embodiment of a mold for making an encapsulated high-frequency circuit.

FIGS. 8-10 are graphs illustrating experimental results that demonstrate performance of an encapsulated high-frequency circuit that embodies the present invention.

### DETAILED DESCRIPTION

Various embodiments of the present invention will be described in detail with reference to the drawings, wherein like reference numerals represent like parts and assemblies throughout the several views. Reference to various embodiments does not limit the scope of the invention, which is limited only by the scope of the claims attached hereto. Additionally, any examples set forth in this specification are not intended to be limiting and merely set forth some of the many possible embodiments for the claimed invention.

FIGS. 1 and 2 illustrate an exemplary embodiment of the present invention. A package 105 is formed with a circuit 100 mounted on a circuit carrier 102. An encapsulent 104 covers the circuit 100 and circuit carrier 102. The circuit carrier 102 can be formed with any type of material suitable for mounting circuits and electrical components. In one possible embodiment, the circuit carrier 102 is formed with a laminate that is non-conductive to electricity, has a low dielectric constant, and is suitable for forming printed circuit boards. Other examples of materials that can form the circuit carrier 102 include ceramic, plastic, or any other electrically insulated circuit carrier material or configuration.

An example of a circuit carrier 102 is an HFC17L laminate chip carrier, which is commercially available from HEI, Incorporated of Victoria, Minn. This chip carrier is an exemplary embodiment only. The circuit carrier 102 can be any type of a structure that is used to mount electrical components and circuits. In other embodiments, for example, the circuit carrier 102 can be formed from a circuit board such as a motherboard or any other printed circuit board.

The circuit carrier 102 has an upper and a lower surface 106 and 108. Bonding pads 112a and 112b are printed on the upper surface 106. The circuit 100 is then mounted on the upper surface 106 and is in electrical communication with the bonding pads 112a and 112b. One or more vias 116a and 116b are formed through the circuit carrier 102. There are soldering pads 114a and 114b on the lower surface 108 of the circuit carrier 102. The vias 116a and 116b provide electrical communication between the circuit 100 and the bonding pads 112a and 112b on the upper surface 106 of the circuit carrier 102 and the soldering pads 114a and 114b on the lower surface 108 of the circuit carrier 102.

The soldering pads 114a and 114b, the bonding pads 112a and 112b, and vias 116a and 116b provide a contact point to connect the circuit 100 mounted on the chip carrier 102 to other circuits and electrical components and are illustrated only as an exemplary embodiment. Other embodiments include structures such as plugs, connectors, or jumper wires to provide electrical communication between the circuit and other electrical components and circuitry that are not mounted on the circuit carrier 102.

The circuit 100 is a combination of passive and/or active electronic components that processes high-frequency electrical signals having a fundamental frequency of about 1 GHz or higher. The circuit 100 can include either an entire circuit, a subsystem of a circuit, or individual electronic components. Examples include transmitters; receivers; computers; amplifiers; mixers; oscillators; timers; microstrips; wire bonds; jumper wires; discrete electrical components or devices such as capacitors, resistors, transistors, and SCRs; microprocessors; microcomputers; programmable logic arrays; and other programmable circuits.

The circuit carrier 102 and the encapsulated circuit 100 can take many forms in addition to the exemplary embodiment described herein. For example, the circuit 100 can be formed from discrete electrical components such as individual resistors and capacitors, and integrated circuits such microwave monolithic integrated circuits (MMIC). The circuit 100 is a subsystem for processing high-frequency signals that is placed in electrical communication with other electrical components to form a complete circuit. Alternatively, the circuit 100 is an entire functioning circuit in and of itself.

The circuit carrier 102 can provide the mounting surface for a subsystem and can be configured for attachment to a motherboard or some other structure. Alternatively, the circuit carrier 102 can be a motherboard or other type of printed circuit board that provides a mounting surface for an entire circuit that is either fully or partially encapsulated. Yet other embodiments include traces printed on the circuit carrier 102. Traces provide signal paths for the high frequency signal being processed by the circuit 100 and can provide a signal path between electrical components that form the circuit 100.

In one embodiment, referring to FIG. 3, the circuit 100 includes a microstrip 118, which is a conductive trace, bonded on the upper surface 120 of a substrate 122. A conductive grounding plane 124 is bonded to the lower surface 126 of the substrate 122 to form a backgrounded scheme. The microstrip 118 provides a controlled-impedance transmission line for a high-frequency signal such as a signal in the microwave spectrum. An advantage of this structure is that most of the electric field generated along the microstrip line 118 is concentrated in the substrate 122 between the microstrip 118 and the grounding plane 124.

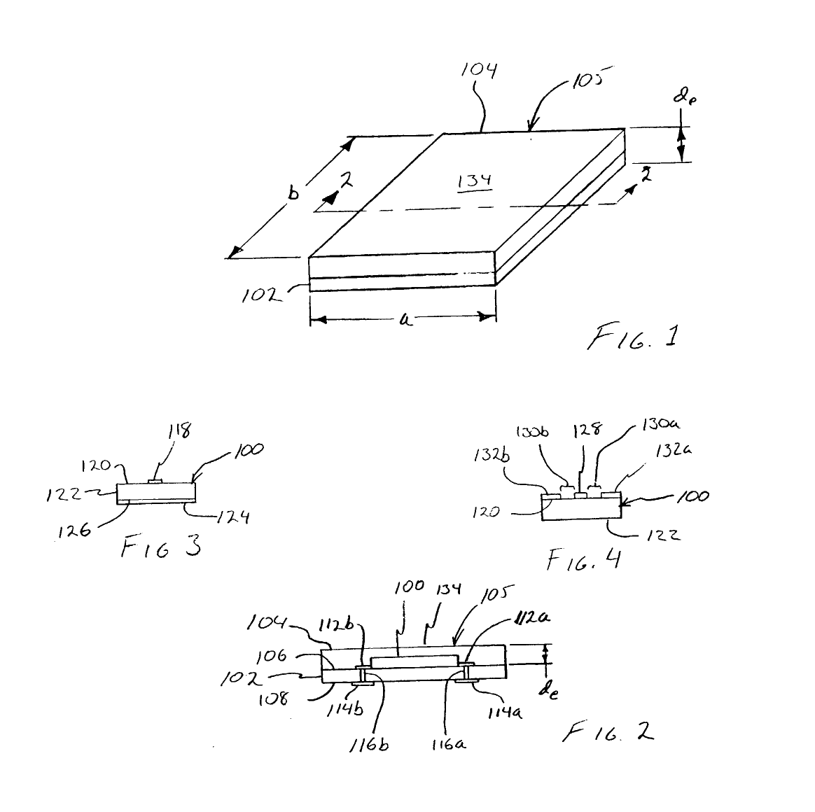

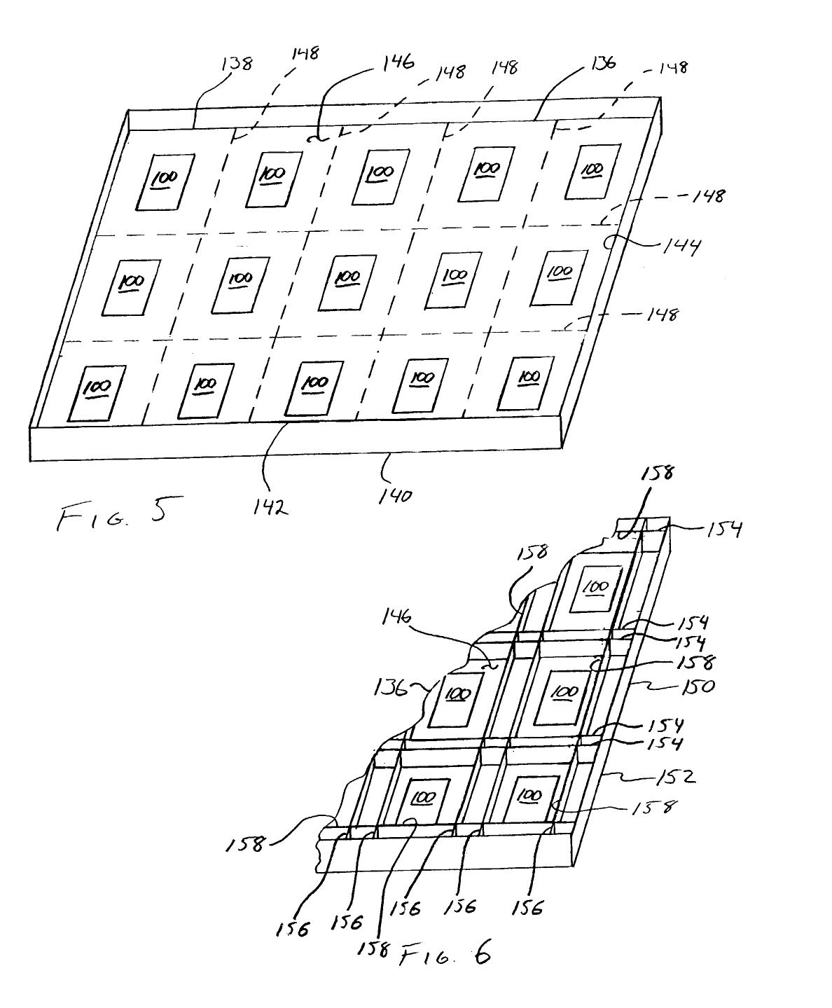

Referring to FIG. 4, an alternative embodiment of the circuit 100 is a coplanar waveguide having a waveguide conductor 128 bonded to the top surface 120 of the substrate 122. First and second grounding planes 132a and 132b are also bonded to the upper surface 120 of the substrate 122 and are positioned on opposite sides of the waveguide conductor 128 forming a coplanar grounding scheme. First and second gaps 130a and 130b are formed between the waveguide conductor 128 and the first and second grounding planes 132a and 132b. In this embodiment, the electric field is concentrated in the first and second gaps 130a and 130b, immediately above the first and second gaps 130a and 130b, and immediately below the first and second gaps 130a and 130b. To minimize distortion of the high-frequency signal propagating along the waveguide conductor 128 that results when the encapsulent material 104 disrupts the electric field, the width of the gaps 130a and 130b, the width of grounding planes 132a and 132b, and the width of the waveguide conductor 128 can be adjusted.

The substrate 122 and grounding schemes disclosed herein are only for exemplary purposes. Other embodiments are possible. For example, the substrate 122 can include both a backgrounded and coplanar grounding scheme. Additionally, the substrate 122 can have any thickness and can be formed from any type of suitable dielectric material such as gallium arsinide (GaAs) or silicon germanium (SiGe).

Referring back to FIGS. 1 and 2, the encapsulent 104 is formed with an encapsulent material that molds and conforms to the circuit 100 and the circuit carrier 102. The encapsulent material has at least two states. The first state is nonhardened and can have a form such as a fluid or gel. The second state is hardened and is cured or otherwise solidified. An example of an encapsulent material includes plastics such as thermoplastics that are applied hot and solidify as they cool. Examples of plastics include Teflon®-brand materials, which is commercially available from E. I. du Pont de Nemours and Company of Wilmington, Del. Another example of an encapsulent material includes epoxies such as thermosetting resins that are applied at an elevated temperature and cure by cross-linking and solidifying as they cool. Examples of epoxies include Fp4650, which is a Hysol®-brand material that is commercially available from Dexter Corporation of Windsor Locks, Conn. Plastics and epoxies are disclosed only as exemplary embodiments. Many other materials that transform from a nonhardened to a hardened state can be used as an encapsulent material.

In the exemplary embodiment illustrated in FIG. 1, the encapsulent 104 covers the entire circuit carrier 102. In alternative embodiment, the encapsulent 104 covers only a portion of the circuit carrier 102. This embodiment allows for screw holes to mount the circuit carrier 102 to a motherboard or to some other structure. In yet other embodiment, the encapsulent 104 covers only a portion of the circuit 100. This embodiment may be advantageous if the circuit 100 includes electrical components such as variable transistors that need to be calibrated or otherwise adjusted. This embodiment also might be advantageous if the encapsulent 104 would adversely affect the performance of a portion of the electric circuit 100. Examples of a portion of the circuit 100 that might be adversely affected include a bandpass filter in which the circuit Q is very high and can be affected by the encapsulent material.

The package 105 has a thickness, dₚ, which is defined by the lower surface 102 of the circuit carrier 102 and an upper surface 134 of the encapsulent 102, and two side lengths, a and b. The thickness, dₑ, of the encapsulent 104 is defined by the upper surface 134 of the circuit carrier 102 and the upper surface 134 of the encapsulent 104. A cross-sectional area is defined by the thickness, dₚ, and the shortest side length, a. Given these dimensions, the lowest resonant frequency of the package 105 is estimated by the equation:

Fᵣ=4.78×10 [symbol] 7*\sqrt{[(3.14/a) [symbol] 2+(3.14/dₚ) [symbol] 2}]/\sqrt{Eᵣ}

where Fᵣ is the lowest resonant frequency (H₁₀₁ mode) in Hertz, Eᵣ is the dielectric constant of the encapsulent material, and the dimensions dₚ and a are in meters. To prevent parasitic resonance in the package 104, the dimensions dₚ and a are determined so that the lowest resonant frequency Fᵣ is higher than the highest frequency in the passband of the circuit.

Other applications in which the package 105 can be used include circuitry that process signals in a bandwidth of about 27 GHz to about 32 GHz for voice communication applications such as mobile telephones, signals in a bandwidth of about 32 GHz to about 38 GHz for digital radio applications, signals up to about 50 GHz for high-speed data communication, and signals at about 77 GHz for vehicle-mounted radar applications. In yet other applications, the circuit 100 will operate in different frequency ranges. For example, some circuits will have a fundamental frequency in the range of about 10 GHz or higher; 20 GHz or higher; 30 GHz or higher; or even 100 GHz or higher.

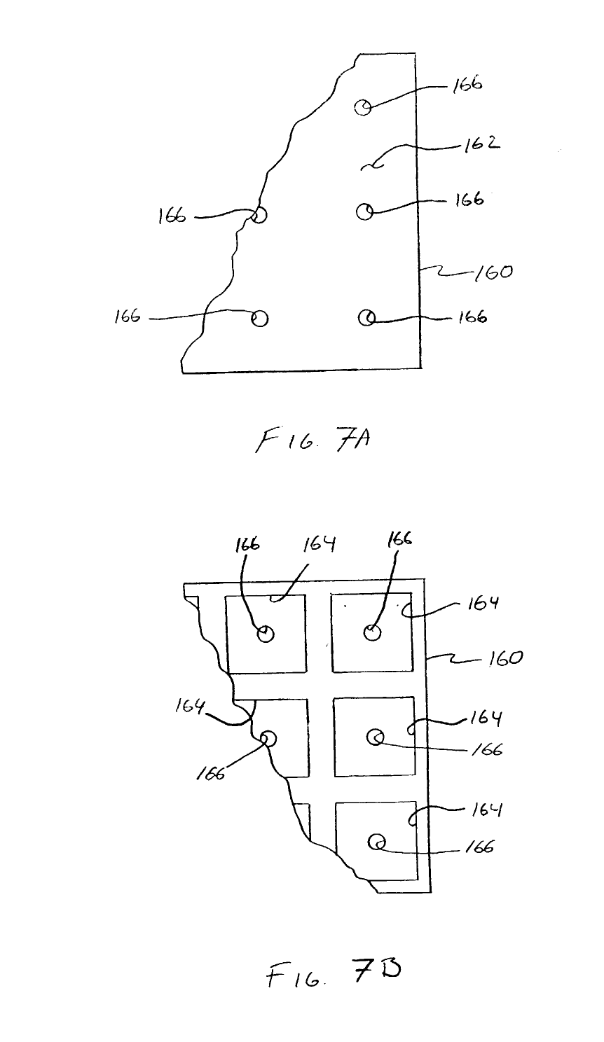

There are many possible ways to manufacture the encapsulated package 105. Referring to FIG. 5, for example, one possible manufacturing method involves a sheet 136 of circuit carrier material. The sheet 136 has a perimeter edge 138 that defines a circumference. A plurality of circuits 100 is then mounted on the sheet 136 of circuit carrier material at regular intervals and a mold in the form of a dam 140 is placed around the perimeter edge 138 of the sheet 136. The dam 140 has a top edge 142 and defines a reservoir 144. The depth from the top edge 142 of the dam 140 to the top surface 146 of the sheet 136 is the same depth as the desired thickness dₑ of the encapsulent 104.

After the circuits 100 are mounted on the sheet 136 and the dam 140 is positioned around the perimeter edge 138 of the sheet 136, the encapsulate material is poured into the reservoir 144 until it reaches the top edge 142 of the dam 140. The encapsulent material is then transformed into a hardened state by curing or otherwise hardening the encapsulent material. After the encapsulent material is in the hardened state, the sheet 136 and encapsulent material is cut between the circuits 100 to form the individual packages 105. In one possible embodiment, the sheet 136 and encapsulent material is cut along the dashed lines 148.

Another possible method of manufacturing is illustrated in FIG. 6. This method is substantially similar to the exemplary method described with reference to FIG. 5 and has a dam 150 that includes an endless outer member 152 that is positioned around the perimeter edge 138 of the sheet 136. Additionally, there is a lattice of cross members. A first group of cross members 154 is orthogonal to a second group of cross member 156. The cross members 154 and 156 define a plurality of reservoirs 158.

The reservoirs 158 and circuits 100 are arranged so that when the dam 150 and the circuits 100 are mounted on the sheet 136, each of the circuits 100 is positioned within one of the reservoirs 158. Non-hardened encapsulent material is then poured into the reservoirs 158 to the top edge 160 of the dam 150. After the encapsulent material is transformed to its hardened state, the dam 150 is removed and the sheet 136 is cut. The dam 150 forms the encapsulent 104 in a discrete area that does not encapsulate the entire upper surface 106 of the circuit carrier 102.

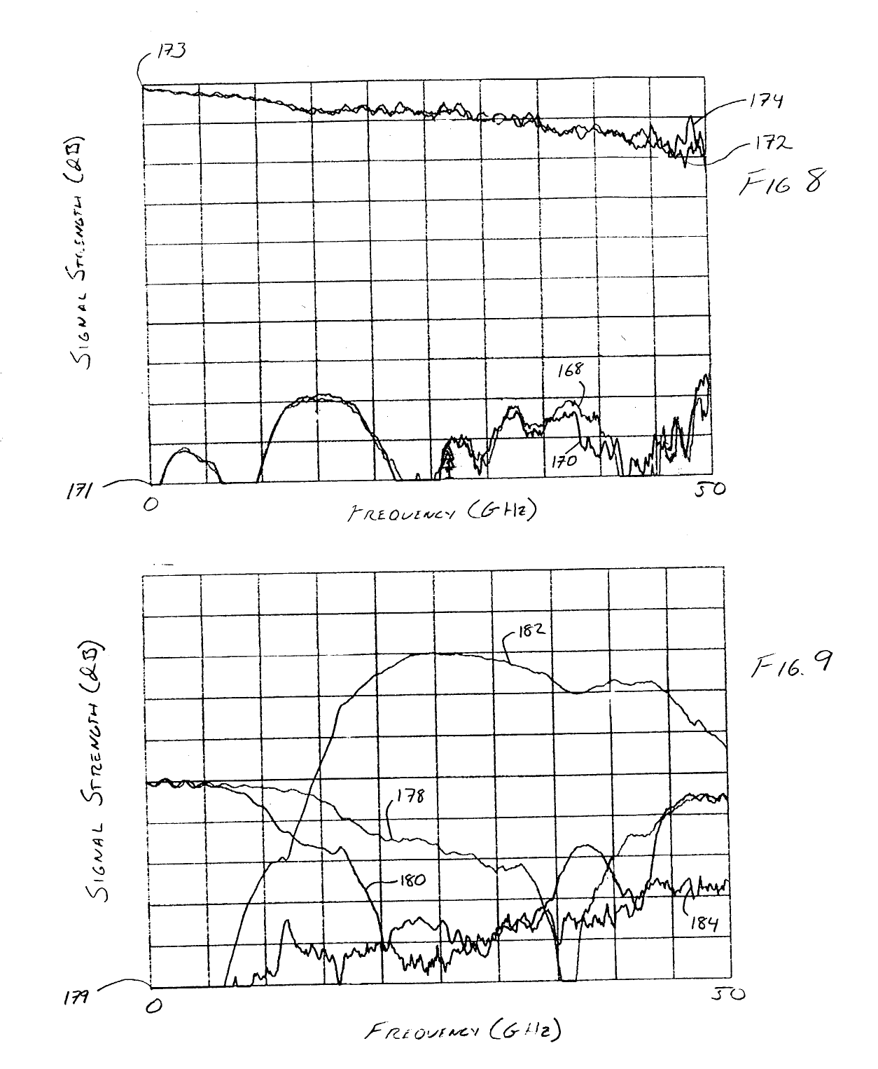

Referring now to FIGS. 7a and 7b, yet another manufacturing method uses an injection mold 160. The mold has a top surface 162 and defines a plurality of reservoirs 164. A plurality of injection ports or holes 166 is defined in the mold 160. Each port 166 extends from the top surface 162 to one of the reservoirs 164. During manufacturing, the mold 160 is positioned against a top surface 168 of the sheet 136 so that each circuit 100 is positioned in one of the reservoirs 164. Non-hardened encapsulent material is then injected through the ports 166 and into each of the reservoirs 164. After the encapsulent material is transformed into a hardened state, the mold 160 is removed and the sheet 136 is cut into separate packages 105.

The manufacturing methods disclosed with reference to FIGS. 5-7 are only exemplary methods. There are many other methods that can be used. For example, the encapsulent material can be sprayed over the circuit 100 and circuit carrier 102. Alternatively, the encapsulent can be a gel, or some other form that has a low viscosity and does not easily flow. In one possible embodiment, such a low viscosity material is applied to the circuit 100 and circuit carrier 102 without the use of a mold.

The following experimental results demonstrate the effectiveness of the invention set forth in the appended claims. The package used for the experiments was similar to the package 105 illustrated in FIGS. 1 and 2. The package 105 was mounted on a test board having an input port that was soldered to the solder pad 114a and an output port that was soldered to the solder pad 114b.

An HP8510C network analyzer was used to measure the S parameters, including the input reflection coefficient (return loss at input port), the output reflection coefficient (return loss at output port), the forward power gain or insertion loss, and the reverse power gain or insertion loss. Performance of the circuit was tested across a bandwidth from 1 GHz to 50 GHz. The S parameters, which are dimensionless expressions, where converted to a decibel scale using the formula: Sᵢⱼ (dB)=20log (Sᵢⱼ).

### EXPERIMENT 1

FIG. 8 illustrates the performance when the circuit is a backgrounded microstrip having an impedance of 50 Ω similar to the circuit illustrated in FIG. 3. The ends of the microstrip line 118 are bonded to the bonding pads 112a and 112b using ball-type bonds. Trace 168 represents the return loss at the input port, and trace 170 represents the return loss at the output port. The scale for the return loss along the x-axis of the graph is 5 dB per crosshatch beginning in the lower left hand corner 171 of the graph. Trace 172 represents the forward power gain (insertion loss from the input to the output), and trace 174 represents the reverse power gain (insertion loss from the output to the input). The scale for the return loss along the x-axis of the graph is 1 dB per crosshatch beginning in the upper left hand corner 173 of the graph. No resonant frequencies are observed in the frequency range from 1 GHz to 50 GHz. Good return loss and low insertion losses are observed with the encapsulent method.

### EXPERIMENT 2

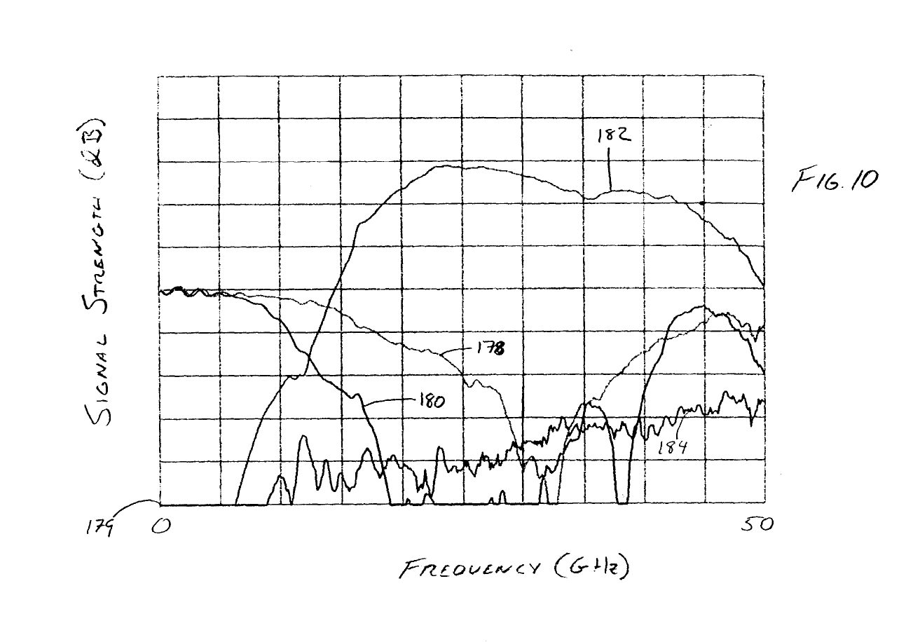

This experiment compares the performance of an HMC261 amplifier that is mounted on an HFC17L laminate chip carrier before and after the amplifier is encapsulated with _Hysol® Fp4650. The amplifier is commercially available from Hittite Microwave Corporation of Chelmsford, Mass. FIG. 9 illustrates performance of the circuit carrier before the amplifier is encapsulated and FIG. 10 illustrates performance of the circuit carrier after the amplifier is encapsulated.

Trace 178 represents the return loss at the input port, and trace 180 represents the return loss at the output port. The scale for the return loss along the x-axis of the graph is 5 dB per crosshatch beginning in the lower left hand corner 179 of the graph. Trace 182 represents the forward voltage gain from the input to the output. The scale for the forward voltage gain along the x-axis of the graph is 5 dB per crosshatch beginning in the lower left hand corner 179 of the graph. Trace 184 represents the reverse voltage gain from the output to the input. The scale for the reverse voltage gain along the x-axis of the graph is 10 dB per crosshatch beginning in the lower left hand corner 179 of the graph.

No resonant frequencies are observed in the frequency range from 1 GHz to 50 GHz. Additionally, the performance of the amplifier after it was encapsulated was similar to the performance before it was encapsulated. The highest forward power gain before encapsulation is 15 dB, and the highest forward power gain after encapsulation is 14.5 dB. At 40 GHz, additionally, the return loss at the output after encapsulation is slightly lower than the return loss before encapsulation.

The various embodiments described above are provided by way of illustration only and should not be construed to limit the invention. Those skilled in the art will readily recognize various modifications and changes that may be made to the present invention without following the example embodiments and applications illustrated and described herein, and without departing from the true spirit and scope of the present invention, which is set forth in the following claims.

The claimed invention is:

1. An apparatus for processing a high-frequency electrical signal, the apparatus comprising:
an electrical circuit arranged to process a signal having a fundamental frequency of about 1 GHz or higher; and
an encapsulent material encapsulating at least a portion of the electrical circuit.

2. The apparatus of claim 1 further comprising:
a circuit carrier having an upper surface, the electrical circuit being mounted on the upper surface and the encapsulent material encapsulates a portion of the upper surface.

3. The apparatus of claim 2 wherein the encapsulent material encapsulates the entire upper surface.

4. The apparatus of claim 2 wherein the encapsulent material encapsulates the entire electrical circuit.

5. The apparatus of claim 2 wherein the circuit carrier is a printed circuit board.

6. The apparatus of claim 2 wherein:
the circuit, encapsulent, and circuit carrier form a package;
the electrical circuit processes a signal within a predetermined frequency range, the predetermined frequency range having a low end and a high end; and
the package has resonant frequencies, the lowest resonant frequency being higher than the high end of the predetermined frequency range.

7. The apparatus of claim 1 wherein the encapsulent material is a thermosetting resin.

8. The apparatus of claim 1 wherein the encapsulent material is a thermoplastic.

9. The apparatus of claim 1 wherein the electrical circuit is arranged to process a signal having a frequency in the range of about 27 GHz to about 32 GHz.

10. The apparatus of claim 1 further comprising:
a substrate, at least a portion of the electrical circuit being mounted on a substrate.

11. The apparatus of claim 10 wherein:
the electrical circuit includes some electrical components mounted on the substrate and some electrical components mounted on the circuit carrier; and
the encapsulent covers at least a portion of the substrate and at least some of the electrical components mounted on the circuit carrier.

12. The apparatus of claim 1 wherein the electrical circuit includes an amplifier, the encapsulent material encapsulating the amplifier.

13. The apparatus of claim 1 wherein the electrical circuit includes an oscillator, the encapsulent material encapsulating the oscillator.

14. The apparatus of claim 1 wherein the electrical circuit includes a mixer, the encapsulent material encapsulating the mixer.

15. The apparatus of claim 1 wherein the electrical circuit includes a microstrip, the encapsulent material encapsulating the microstrip.

16. The apparatus of claim 1 wherein the electrical circuit includes a programmable circuit, the encapsulent material encapsulating the programmable circuit.

17. The apparatus of claim 1 wherein the electrical circuit includes a microwave monolithic integrated circuit, the encapsulent material encapsulating the microwave monolithic integrated circuit.

18. The apparatus of claim 1 wherein the electrical circuit includes an integrated circuit, the encapsulent material encapsulating the integrated circuit.

19. An apparatus for processing a high-frequency electrical signal, the apparatus comprising:
a circuit carrier;
an electrical circuit mounted on the circuit carrier, the electrical circuit processing a signal within a predetermined frequency range, the predetermined frequency range having a low end, the low end of the of the predetermined frequency range being about 20 GHz or higher;
an encapsulent material encapsulating at least a portion of the electrical circuit; and
wherein the circuit carrier, electrical circuit, and encapsulent material form a package, the package having resonant frequencies, the resonant frequencies being outside the predetermined frequency range.

20. The apparatus of claim 19 wherein the encapsulent material encapsulates the entire circuit.

21. The apparatus of claim 19 wherein the circuit carrier has an upper surface and the encapsulent material encapsulates the entire circuit and the entire upper surface of circuit carrier.

22. The apparatus of claim 19 wherein the encapsulent material encapsulates only a portion of the electrical circuit.

23. The apparatus of claim 19 wherein the encapsulent material encapsulates only a portion of the circuit carrier.

24. A method of manufacturing an apparatus for processing a high-frequency electrical signal, the method comprising:
providing a circuit carrier, a plurality of circuits being mounted on the circuit carrier;
encapsulating at least a portion of each of the circuits; and
separating the circuit carrier into two or more individual boards so that each board has at least one circuit and the encapsulent is around at least a portion of the at least one circuit on each board.

25. The method of claim 24 wherein the act of encapsulating at least a portion of each circuit comprises:
positioning the circuit carrier in a mold and forming a reservoir defined by the circuit carrier and the mold;
pouring a fluid encapsulent material into the reservoir; and
hardening the encapsulent material.

26. The method of claim 25 wherein the act of pouring a fluid encapsulent material into the reservoir includes pouring a non-hardened plastic into the reservoir.

27. The method of claim 25 wherein the act of pouring a fluid encapsulent material into the reservoir includes pouring a non-hardened epoxy into the reservoir.

28. The method of claim 26 wherein the circuit carrier has a perimeter edge and the mold is formed from a dam, further wherein:
the act of positioning the circuit carrier in a mold and forming a reservoir comprises positioning the dam against the edge of the circuit carrier so that the entire surface of the circuit carrier forms the bottom of the reservoir.

29. The method of claim 25 wherein the circuit carrier has a surface and the act of forming a reservoir comprises forming a plurality of reservoirs so that a bottom portion of each reservoir is formed from a separate portion of the circuit carrier.
